(19) United States
(12) Patent Application Publication
(10) Pub. No.: US 2026/0107498 A1
(43) Pub. Date: Apr. 16, 2026

(54) SEMICONDUCTOR STRUCTURE AND METHOD FOR MANUFACTURING SAME

(71) Applicant: CXMT Corporation, Hefei (CN)

(72) Inventor: Yi Tang, Hefei (CN)

(73) Assignee: CXMT Corporation, Hefei (CN)

(21) Appl. No.: 19/209,751

(22) Filed: May 15, 2025

Related U.S. Application Data
(63) Continuation of application No. PCT/CN2025/076598, filed on Feb. 10, 2025.

(30) Foreign Application Priority Data
Oct. 16, 2024 (CN) 202411449809.2

(51) Int. Cl. H10D 30/63; H10D 30/01; H10D 62/80

(52) U.S. Cl. CPC H10D 30/63; H10D 30/025; H10D 62/875

(57) ABSTRACT

The method includes: providing an initial structure including a plurality of dielectric layers and a plurality of conductive layers, where each of the plurality of conductive layers includes a plurality of conductive strips, a plurality of first holes penetrate through the plurality of conductive strips along a first direction; laterally thinning the plurality of conductive strips to form a plurality of first trenches; forming a plurality of first indium gallium zinc oxides in the plurality of first trenches; laterally thinning the plurality of dielectric layers to expose part of the plurality of first indium gallium zinc oxides; forming a plurality of second indium gallium zinc oxides on the surfaces of the plurality of exposed first indium gallium zinc oxides, where the concentration of indium in the plurality of first indium gallium zinc oxides is higher than that of indium in the plurality of second indium gallium zinc oxides.

This application is a continuation of PCT/CN2025/076598, filed on Feb. 10, 2025, which claims priority to Chinese Patent Application No. 202411449809.2, filed with China National Intellectual Property Administration on Oct. 16, 2024 and entitled “SEMICONDUCTOR STRUCTURE AND METHOD FOR MANUFACTURING SAME”, the content of which is incorporated herein by reference in its entirety.

### TECHNICAL FIELD

The present disclosure relates to the field of semiconductors, and particularly to a semiconductor structure and a method for manufacturing the same.

### BACKGROUND

In a dynamic random access memory (DRAM) manufacturing process, a method for manufacturing a buried bit line is often used. With the continuous reduction of the size in the semiconductor process, the existing manufacturing process cannot meet the requirements gradually. At present, a 3D DRAM based on an indium gallium zinc oxide (IGZO) material is also the focus of research in the industry due to the excellent anti-leakage characteristic of the material, low cost and a relatively simple process.

However, the contact resistance between IGZO and a metal electrode is relatively large, which affects the performance of a device. Therefore, how to reduce the contact resistance between the IGZO and the metal electrode so as to improve the device performance is a problem to be solved at present.

### SUMMARY

The technical problem to be solved by the present disclosure is to reduce the contact resistance between IGZO and a metal electrode so as to improve the device performance, and thus the present disclosure provides a semiconductor structure and a method for manufacturing the same.

In order to solve the above problem, the present disclosure provides a method for manufacturing a semiconductor structure. The method includes: providing an initial structure including a plurality of dielectric layers and a plurality of conductive layers, which are sequentially stacked along a first direction, where each of the plurality of conductive layers includes a plurality of conductive strips extending along a second direction and spaced apart along a third direction, a plurality of first holes penetrate through the plurality of dielectric layers and the plurality of conductive strips along the first direction, and each of the plurality of conductive strips is separated by the corresponding first hole into two parts, which are independent of each other, in the second direction; laterally thinning the plurality of conductive strips along the second direction to form a plurality of first trenches between two adjacent dielectric layers; forming a plurality of first indium gallium zinc oxides in the plurality of first trenches; laterally thinning the plurality of dielectric layers along the second direction to expose part of the plurality of first indium gallium zinc oxides and form a plurality of second trenches between two adjacent first indium gallium zinc oxides; forming a plurality of second indium gallium zinc oxides on surfaces of the plurality of exposed first indium gallium zinc oxides, where a concentration of indium in the plurality of first indium gallium zinc oxides is higher than that of indium in the plurality of second indium gallium zinc oxides; and forming a gate structure in the plurality of first holes and the plurality of second trenches.

In some embodiments, after the step of laterally thinning the plurality of dielectric layers along the second direction, the method further includes: performing plasma treatment to the plurality of exposed first indium gallium zinc oxides so as to form a plurality of oxygen holes in the plurality of first indium gallium zinc oxides.

In some embodiments, in the process of performing the plasma treatment to the plurality of exposed first indium gallium zinc oxides, the plasma concentration decreases with a treatment time.

In some embodiments, in the step of laterally thinning the plurality of dielectric layers along the second direction, the plurality of dielectric layers are laterally thinned along the second direction for multiple times to partially expose the plurality of first indium gallium zinc oxides; and after the plurality of dielectric layers are thinned laterally along the second direction each time, treatment to the plurality of exposed first indium gallium zinc oxides is performed, so as to form a plurality of oxygen holes in the plurality of first indium gallium zinc oxides.

In some embodiments, in the step of performing the treatment to the plurality of exposed first indium gallium zinc oxides after the plurality of dielectric layers are laterally thinned along the second direction each time, plasma treatment to the plurality of exposed first indium gallium zinc oxides is performed after the plurality of dielectric layers are laterally thinned each time, and the plasma concentration decreases with an increase of the times of laterally thinning the plurality of dielectric layers so as to form an oxygen hole concentration gradient in the plurality of first indium gallium zinc oxides.

In some embodiments, after performing the plasma treatment to the plurality of first indium gallium zinc oxides, the method further includes: annealing the plurality of first indium gallium zinc oxides.

In some embodiments, the molar composition ratio of indium, gallium and zinc in the plurality of first indium gallium zinc oxides is (9-10):1:1.

In order to solve the above problem, the present disclosure further provides a semiconductor structure. The semiconductor structure includes: an initial structure including a plurality of dielectric layers and a plurality of conductive layers, which are sequentially stacked along a first direction, where each of the conductive layers includes a plurality of conductive strips extending along a second direction and spaced apart along a third direction, each of the plurality of conductive strips is separated into a first part and a second part, which are independent of each other, in the second direction, and opposite end parts of the first parts and the second parts are recessed into the plurality of dielectric layers; a plurality of first indium gallium zinc oxides respectively disposed at the opposite end parts of the first parts and the second parts of the plurality of conductive strips, where end parts of the plurality of first indium gallium zinc oxides protrude from the plurality of dielectric layers; a plurality of second indium gallium zinc oxides covering surfaces of regions of the plurality of first indium gallium zinc oxides protruding from the plurality of dielectric layers, where a concentration of indium in the plurality of first indium gallium zinc oxides is higher than that of indium in the plurality of second indium gallium zinc oxides; and a gate structure covering the plurality of second indium gallium zinc oxides.

In some embodiments, a concentration of a plurality of oxygen holes at an end of each of the plurality of first indium gallium zinc oxides proximal to the corresponding second indium gallium zinc oxide is higher than a concentration of a plurality of oxygen holes on a side of the first indium gallium zinc oxide distal to the second indium gallium zinc oxide.

In some embodiments, the concentration of the plurality of oxygen holes in the plurality of first indium gallium zinc oxides exhibits a gradient decrease.

In some embodiments, the molar composition ratio of indium, gallium and zinc in the plurality of first indium gallium zinc oxides is (9-10):1:1.

In some embodiments, the gate structure, the plurality of second indium gallium zinc oxides, the plurality of first indium gallium zinc oxides and the plurality of conductive strips form a transistor, the first parts of the plurality of conductive strips serve as a source region of the transistor, and the second parts of the plurality of conductive strips serve as a drain region of the transistor.

In some embodiments, the gate structure further includes a gate and gate dielectric layers, where the gate dielectric layers are at least disposed between the gate and the plurality of second indium gallium zinc oxides.

According to the method for manufacturing a semiconductor structure, by forming the plurality of first indium gallium zinc oxides with a higher indium concentration between the plurality of second indium gallium zinc oxides and the plurality of conductive strips, the contact resistance between the plurality of second indium gallium zinc oxides and the plurality of conductive strips is reduced. Moreover, the plurality of first indium gallium zinc oxides and the plurality of second indium gallium zinc oxides are made of the same material, thereby skipping forming an interface between the plurality of first indium gallium zinc oxides and the plurality of second indium gallium zinc oxides, such that further reduction in the contact resistance between the plurality of second indium gallium zinc oxides and the plurality of conductive strips is facilitated. Furthermore, an oxygen hole concentration gradient is formed in the plurality of first indium gallium zinc oxides, such that the electric leakage of the transistor can be prevented, and thus the power consumption of a device can be reduced. In addition, by annealing the plurality of first indium gallium zinc oxides, the damage to the surfaces of the plurality of first indium gallium zinc oxides can be reduced, and the electrical properties thereof, such as conductivity, carrier concentration and mobility, can be improved.

According to the semiconductor structure, by forming the plurality of first indium gallium zinc oxides with a higher indium concentration between the plurality of second indium gallium zinc oxides and the plurality of conductive strips, the contact resistance between the plurality of second indium gallium zinc oxides and the plurality of conductive strips is reduced. Moreover, the plurality of first indium gallium zinc oxides and the plurality of second indium gallium zinc oxides are made of the same material, thereby skipping forming an interface between the plurality of first indium gallium zinc oxides and the plurality of second indium gallium zinc oxides, such that further reduction in the contact resistance between the plurality of second indium gallium zinc oxides and the plurality of conductive strips is facilitated.

It should be understood that both the foregoing general description and the subsequent detailed description are exemplary and explanatory only and are not intended to limit the present disclosure. Techniques, methods, and devices known by those of ordinary skill in the relevant arts may not be discussed in detail, but are intended to be part of the authorized specification where appropriate.

### BRIEF DESCRIPTION OF DRAWINGS

In order to more clearly illustrate technical solutions in embodiments of the present disclosure, drawings that are required in the description of the embodiments will be briefly described below. Apparently, the drawings in the following description are only some specific embodiments of the present disclosure, and other drawings may be derived by those of ordinary skill in the art without inventive efforts.

FIG. 1 is a schematic structural diagram of a semiconductor structure in the prior art;

FIG. 2 is a step flowchart of a method for manufacturing a semiconductor structure according to an embodiment of the present disclosure;

FIG. 3A is a process flowchart of a method for manufacturing a semiconductor structure according to an embodiment of the present disclosure;

FIG. 3B is a process flowchart of a method for manufacturing a semiconductor structure according to an embodiment of the present disclosure;

FIG. 3C is a process flowchart of a method for manufacturing a semiconductor structure according to an embodiment of the present disclosure;

FIG. 3D is a process flowchart of a method for manufacturing a semiconductor structure according to an embodiment of the present disclosure;

FIG. 3E is a process flowchart of a method for manufacturing a semiconductor structure according to an embodiment of the present disclosure;

FIG. 3F is a process flowchart of a method for manufacturing a semiconductor structure according to an embodiment of the present disclosure;

FIG. 3G is a process flowchart of a method for manufacturing a semiconductor structure according to an embodiment of the present disclosure;

FIG. 3H is a process flowchart of a method for manufacturing a semiconductor structure according to an embodiment of the present disclosure;

FIG. 4A is a process flowchart of a method for manufacturing a semiconductor structure according to another embodiment of the present disclosure;

FIG. 4B is a process flowchart of a method for manufacturing a semiconductor structure according to another embodiment of the present disclosure;

FIG. 4C is a process flowchart of a method for manufacturing a semiconductor structure according to another embodiment of the present disclosure;

FIG. 4D is a process flowchart of a method for manufacturing a semiconductor structure according to another embodiment of the present disclosure.

### DESCRIPTION OF EMBODIMENTS

The technical solutions in the embodiments of the present disclosure will be clearly and completely described below with reference to the accompanying drawings. Apparently, the described embodiments are only some of the embodiments of the present disclosure, and not all embodiments. All other embodiments, which are derived by those skilled in the art from the embodiments of the present disclosure without inventive efforts, are intended to fall within the scope of protection of the present disclosure.

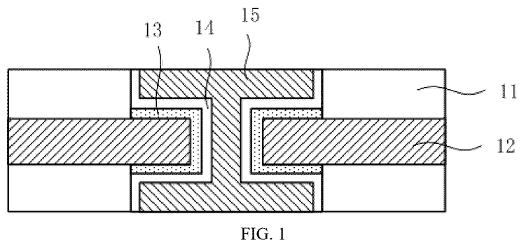

Referring to FIG. 1, a schematic structural diagram of a semiconductor structure in the prior art is shown. As shown in FIG. 1, the semiconductor structure includes: silicon dioxide layers 11, a metal electrode 12, annular channels 13, gate dielectric layers 14, and a gate 15. A plurality of silicon dioxide layers 11 are sequentially laminated, and the metal electrode 12 is located inside the laminated silicon dioxide layers 11. The metal electrode 12 is divided into two parts, which are respectively located on two sides of the annular channels 13, and the annular channels 13 are located on the surfaces of the part of the metal electrode 12 protruding from the silicon dioxide layers 11. The gate dielectric layers 14 and the gate 15 are located inside the silicon dioxide layers 11 and between the two parts of the metal electrode 12, and are located on the surfaces of the annular channels 13. The metal electrode 12 of the semiconductor structure is made of metal tungsten, the annular channel 13 is made of indium gallium zinc oxide, and the contact resistance between the metal tungsten and the indium gallium zinc oxide is relatively large, such that the device performance is greatly affected.

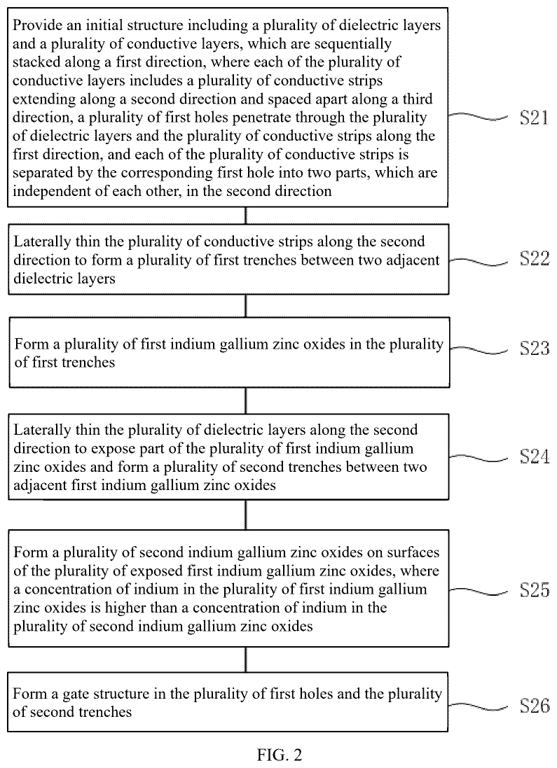

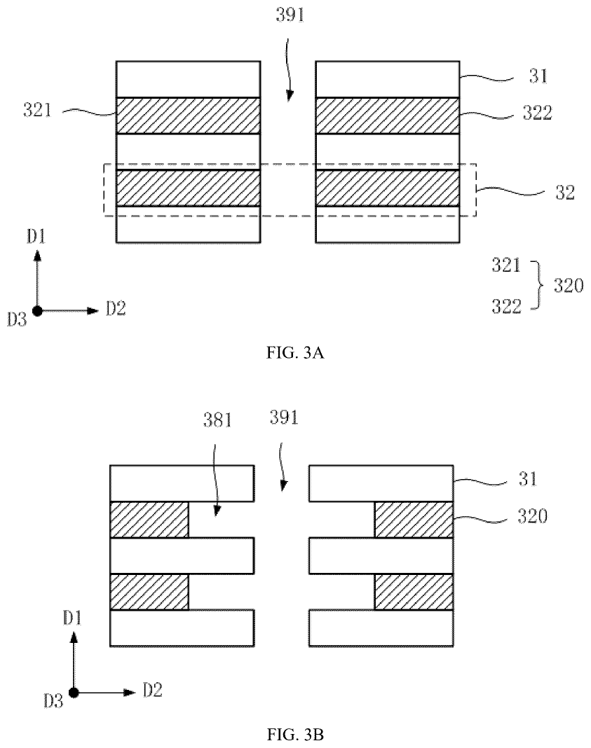

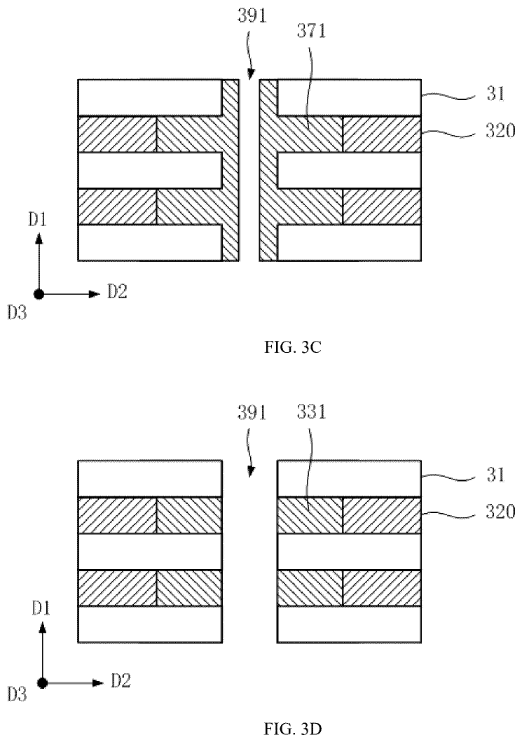

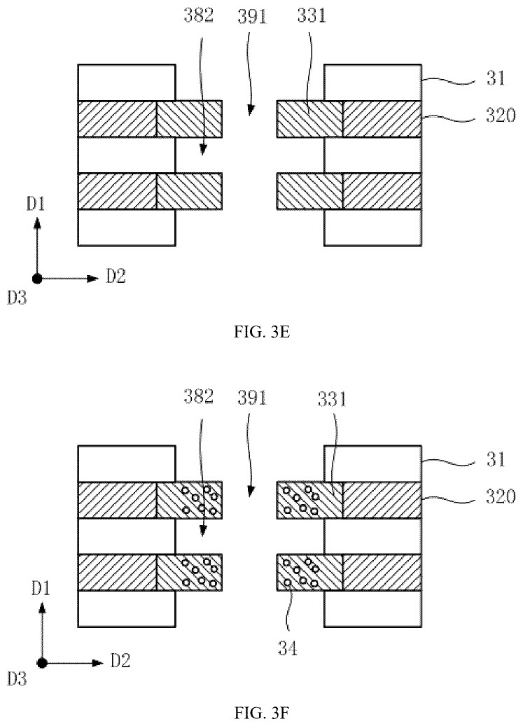

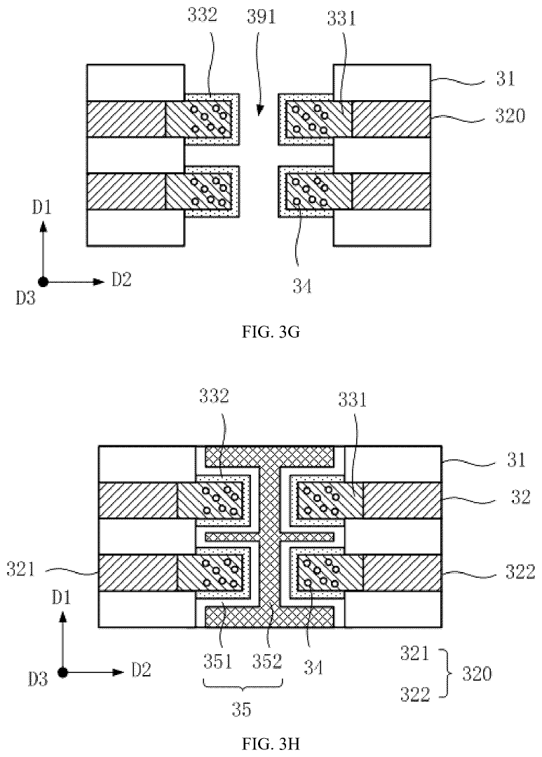

In order to solve the above problem, the present disclosure provides a method for manufacturing a semiconductor structure. Referring to FIG. 2 and FIGS. 3A to 3H, FIG. 2 is a step flowchart of a method for manufacturing a semiconductor structure according to an embodiment of the present disclosure; and FIGS. 3A to 3H are process flowcharts of a method for manufacturing a semiconductor structure according to an embodiment of the present disclosure. As shown in FIG. 2, the method for manufacturing a semiconductor structure includes: step S21, providing an initial structure including a plurality of dielectric layers and a plurality of conductive layers, which are sequentially stacked along a first direction, where each of the plurality of conductive layers includes a plurality of conductive strips extending along a second direction and spaced apart along a third direction, a plurality of first holes penetrates through the plurality of dielectric layers and the plurality of conductive strips along the first direction, and each of the plurality of conductive strips is separated by the corresponding first hole into two parts, which are independent of each other, in the second direction; step S22, laterally thinning the plurality of conductive strips along the second direction to form a plurality of first trenches between two adjacent dielectric layers; step S23, forming a plurality of first indium gallium zinc oxides in the plurality of first trenches; step S24, laterally thinning the plurality of dielectric layers along the second direction to expose part of the plurality of first indium gallium zinc oxides and form a plurality of second trenches between two adjacent first indium gallium zinc oxides; step S25, forming a plurality of second indium gallium zinc oxides on the surfaces of the plurality of exposed first indium gallium zinc oxides, where the concentration of indium in the plurality of first indium gallium zinc oxides is higher than that of indium in the plurality of second indium gallium zinc oxides; and step S26, forming gate structures in the plurality of first holes and the plurality of second trenches.

Referring to FIG. 3A and step S21, the initial structure is provided. The initial structure includes the plurality of dielectric layers 31 and the plurality of conductive layers 32, which are sequentially stacked along the first direction D1, where each of the conductive layers 32 includes the plurality of conductive strips 320 extending along the second direction D2 and spaced apart along the third direction D3, the plurality of first holes 391 penetrate through the plurality of dielectric layers 31 and the plurality of conductive strips 320 along the first direction D1, and each of the conductive strips 320 is separated by the corresponding first hole 391 into two parts, which are independent of each other, in the second direction D2. As shown in FIG. 3A, the two mutually independent parts of each of the plurality of conductive strips are a first part 321 and a second part 322. In some embodiments, the dielectric layers 31 are made of silicon oxide and the conductive strips 320 are made of metal, for example, tungsten.

The first direction D1 is a direction perpendicular to the surface of the initial structure, the second direction D2 and the third direction D3 are directions parallel to the surface of the initial structure, and the second direction D2 is perpendicular to the third second D3, and in this embodiment, the first direction D1 is exemplified as a Z direction in a Cartesian coordinate system, the second direction D2 is exemplified as an X direction in the Cartesian coordinate system, and the third direction is exemplified as a Y direction in the Cartesian coordinate system.

Referring to FIG. 3B and step S22, the plurality of conductive strips 320 are laterally thinned along the second direction D2 to form the plurality of first trenches 381 between two adjacent dielectric layers 31. In some embodiments, on the side walls of the plurality of first holes 391, the plurality of conductive strips 320 are laterally thinned along the second direction D2 by an etching process, and the parts of the plurality of conductive strips 320 exposed on the side walls of the plurality of first holes 391 are removed to form the plurality of first trenches 381.

Referring to FIG. 3D and step S23, the plurality of first indium gallium zinc oxides 331 are formed in the plurality of first trenches 381. In some embodiments, the step of forming the plurality of first indium gallium zinc oxides 331 in the plurality of first trenches 381 further includes the following step:
depositing a plurality of first indium gallium zinc oxide material layers 371 in the plurality of first holes 391 and the plurality of first trenches 381 (shown in FIG. 3B), as shown in FIG. 3C. In some embodiments, the molar composition ratio of indium, gallium and zinc in the plurality of first indium gallium zinc oxide material layers 371 is (9-10):1:1; namely, a plurality of material layers with a high indium-gallium ratio are formed. In this embodiment, the plurality of first indium gallium zinc oxide material layers 371 can be deposited in the plurality of first holes 391 and the plurality of first trenches 381 by an atomic layer deposition process, and the ratio of indium to gallium is controlled by the gas flow of a precursor.

As shown in FIG. 3D, the plurality of first indium gallium zinc oxide material layers 371 in the plurality of first holes 391 are removed, and the plurality of first indium gallium zinc oxide material layers 371 in the plurality of first trenches 381 (shown in FIG. 3B) are remained as the plurality of first indium gallium zinc oxides 331. In this embodiment, the plurality of first indium gallium zinc oxide material layers 371 in the plurality of first holes 391 are removed by dry etching.

After the above step is completed, the plurality of first indium gallium zinc oxides 331 located in the plurality of first trenches 381 (shown in FIG. 3B) can be obtained.

In some embodiments, the molar composition ratio of indium, gallium and zinc in the plurality of indium gallium zinc oxides 331 is (9-10):1:1; namely, the first indium gallium zinc oxide 331 is of a high-indium structure.

Referring to FIG. 3E and step S24, the plurality of dielectric layers 31 are thinned laterally along the second direction D2 to expose part of the plurality of first indium gallium zinc oxides 331 and form the plurality of second trenches 382 between two adjacent indium gallium zinc oxides 331. In some embodiments, on the side walls of the plurality of first holes 391, the plurality of dielectric layers 31 may be laterally thinned along the second direction D2 by an etching process, and the removed regions of the plurality of dielectric layers 31 form the plurality of second trenches 382.

As shown in FIG. 3F, in some embodiments, after the step of laterally thinning the plurality of dielectric layers 31 along the second direction D2, the following step is further included: performing plasma treatment to the plurality of exposed first indium gallium zinc oxides 331 so as to form a plurality of oxygen holes 34 in the plurality of first indium gallium zinc oxides 331. The plurality of oxygen holes 34 are formed in the plurality of first indium gallium zinc oxides 331, such that the electric leakage of the semiconductor structure can be prevented, and thus the power consumption of a device can be reduced.

In some embodiments, the plasma treatment includes, but is not limited to, hydrogen ion plasma treatment, indium ion doping, argon ion plasma treatment, and other methods for increasing the oxygen hole concentration. In this embodiment, the plasma treatment to the plurality of first indium gallium zinc oxides 331 is performed by a hydrogen ion plasma treatment process, and hydrogen ions bombard metal-oxygen bonds to break the metal-oxygen bonds so as to form the plurality of oxygen holes in the plurality of first indium gallium zinc oxides.

In this embodiment, in the process of performing the plasma treatment to the plurality of exposed first indium gallium zinc oxides 331, the plasma concentration decreases with a treatment time. The plasma concentration decreases with the time, and likewise an oxygen hole concentration gradient can be formed in the plurality of first indium gallium zinc oxides 331, such that the electric leakage of a transistor can be prevented, and thus the power consumption of the device can be reduced.

After performing the plasma treatment to the plurality of first indium gallium zinc oxides 331, the method further includes: annealing the plurality of first indium gallium zinc oxides 331. By an annealing process, the damage of the plasma treatment to the plurality of first indium gallium zinc oxides 331 can be reduced, and the electrical properties thereof, such as conductivity, carrier concentration and mobility, can be improved.

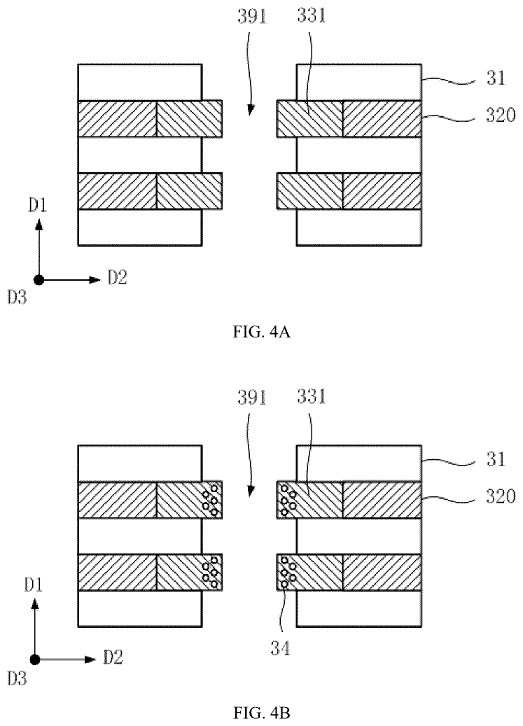

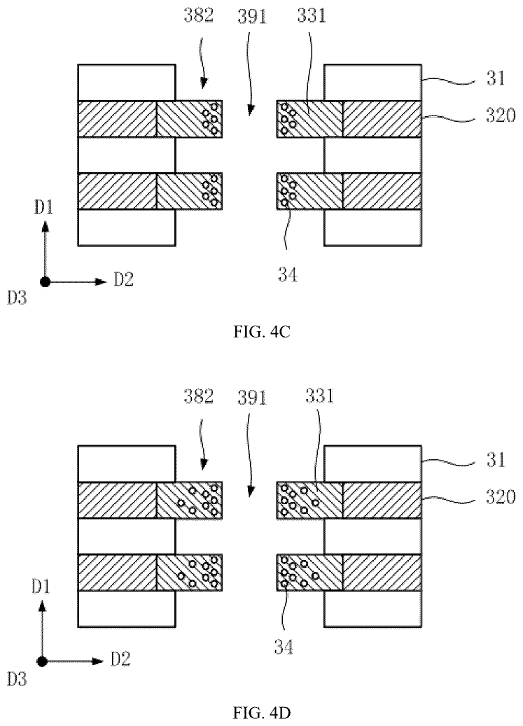

In the above embodiments, the plasma treatment to the plurality of first indium gallium zinc oxides 331 is performed after the plurality of dielectric layers 31 are thinned along the second direction; and in other embodiments, in the step of laterally thinning the plurality of dielectric layers 31 along the second direction D2, the plurality of dielectric layers 31 may be laterally thinned along the second direction D2 for multiple times to partially expose the plurality of first indium gallium zinc oxides 331, and treatment to the plurality of exposed first indium gallium zinc oxides 331 is performed after the plurality of dielectric layers 31 are laterally thinned along the second direction D2 each time so as to form the plurality of oxygen holes 34 in the plurality of first indium gallium zinc oxides 331. The plurality of oxygen holes 34 are formed in the plurality of first indium gallium zinc oxides 331, such that the electric leakage of the transistor can be prevented, and thus the power consumption of the device can be reduced. Referring to FIGS. 4A to 4D, process flowcharts of plasma treatment to the plurality of first indium gallium zinc oxides 331 according to another embodiment are shown.

Referring to the embodiment shown in FIGS. 4A to 4D:
As shown in FIG. 4A, part of the plurality of dielectric layers 31 are thinned laterally along the second direction D2 to expose the plurality of first indium gallium zinc oxides 331. For example, the plurality of dielectric layers 31 are laterally thinned along the second direction D2 by an etching process.
As shown in FIG. 4B, the plasma treatment to the plurality of exposed first indium gallium zinc oxides 331 is performed so as to form the plurality of oxygen holes 34 in the plurality of first indium gallium zinc oxides 331. In some embodiments, the plasma treatment includes, but is not limited to, hydrogen ion plasma treatment, indium ion doping, argon ion plasma treatment, and other methods for increasing the oxygen hole concentration. In this embodiment, the plasma treatment to the plurality of first indium gallium zinc oxides 331 is performed by a hydrogen ion plasma treatment process.
As shown in FIG. 4C, part of the plurality of dielectric layers 31 are further thinned laterally along the second direction D2 to expose the plurality of first indium gallium zinc oxides 331 to target positions, and the plurality of second trenches 382 are formed between two adjacent first indium gallium zinc oxides 331.
As shown in FIG. 4D, the plasma treatment to the plurality of exposed first indium gallium zinc oxides 331 is performed so as to form the plurality of oxygen holes 34 in the plurality of first indium gallium zinc oxides 331. In some embodiments, the plasma treatment includes, but is not limited to, hydrogen ion plasma treatment, indium ion doping, argon ion plasma treatment, and other methods for increasing the oxygen hole concentration. In this embodiment, the plasma treatment to the plurality of first indium gallium zinc oxides 331 is performed by a hydrogen ion plasma treatment process.

In this step, the plasma treatment to the entire exposed region of the plurality of first indium gallium zinc oxides 331 is performed, and the oxygen hole concentration is superimposed in the region that has been subjected to plasma treatment in the previous time; and in this step, the oxygen hole concentration in the region that is subjected to plasma treatment for the first time is the oxygen hole concentration formed by the current plasma treatment, such that an oxygen hole concentration gradient is formed in the exposed region of the plurality of first indium gallium zinc oxides 331.

In some embodiments, in the step of performing the treatment to the plurality of exposed first indium gallium zinc oxides 331 after the plurality of dielectric layers 31 are laterally thinned each time, plasma treatment to the plurality of exposed first indium gallium zinc oxides 331 is performed after the plurality of dielectric layers 31 are laterally thinned each time, and the plasma concentration decreases with an increase of the times of laterally thinning the plurality of dielectric layers 31 so as to further form an oxygen hole concentration gradient in the plurality of first indium gallium zinc oxides 331. An oxygen hole concentration gradient is formed in the plurality of first indium gallium zinc oxides 331, such that the conductive effect can be further improved, and thus the contact resistance can be reduced.

For an embodiment, in which the plurality of dielectric layers 31 are thinned step by step and the plasma treatment to the plurality of exposed first indium gallium zinc oxides 331 is performed after the plurality of dielectric layers 31 are laterally thinned along the second direction D2 each time, an annealing process is performed in a unified manner after all thinning and plasma treatment steps are completed. By the annealing process, the damage of the plasma treatment to the plurality of first indium gallium zinc oxides 331 can be reduced, and the electrical properties thereof, such as conductivity, carrier concentration and mobility, can be improved.

In the above embodiment, two times of laterally thinning the plurality of dielectric layers 31 and two times of performing plasma treatment are only schematically illustrated, and in other embodiments, multiple times of laterally thinning the plurality of dielectric layers 31 and multiple times of performing plasma treatment, for example, three times or more, may be accepted.

With further reference to FIG. 2, FIG. 3G and step S25, a plurality of second indium gallium zinc oxides 332 are formed on the surfaces of the plurality of exposed first indium gallium zinc oxides 331, and the concentration of indium in the first indium gallium zinc oxide 331 is higher than that of indium in the second indium gallium zinc oxide 332. The plurality of second indium gallium zinc oxides 332 cover exposed surfaces of the plurality of first indium gallium zinc oxides 331 and can be electrically connected with the plurality of conductive strips 320 through the plurality of first indium gallium zinc oxides 331. According to the semiconductor structure of the present disclosure, the contact resistance between the plurality of second indium gallium zinc oxides 332 and the plurality of conductive strips 320 is reduced by forming the plurality of first indium gallium zinc oxides 331 with a higher indium concentration between the plurality of second indium gallium zinc oxides 332 and the plurality of conductive strips 320. In some embodiments, the plurality of second indium gallium zinc oxides 332 may be deposited by an atomic layer deposition process.

In this step, the plurality of second indium gallium zinc oxides 332 cover only the exposed surfaces of the plurality of first indium gallium zinc oxides 331, the surfaces of the plurality of dielectric layers 31 are not covered with the plurality of second indium gallium zinc oxides 332, and the plurality of second trenches 382 are not fully filled with the plurality of second indium gallium zinc oxides 332.

In addition, in an embodiment, in which the plurality of dielectric layers 31 are laterally thinned for multiple times and the plasma treatment is performed for two times, the plurality of second indium gallium zinc oxides 332 formed in step S25 are the same as that in this embodiment.

Referring to FIG. 1, FIG. 3H and step S26, a gate structure 35 is formed in the plurality of first holes 391 and the plurality of second trenches 382. A method for forming the gate structure 35 includes, but is not limited to, thermal oxidation, chemical vapor deposition, plasma chemical vapor deposition, and atomic layer deposition. The gate structure 35 further includes a gate 352 and gate dielectric layers 351, where the gate dielectric layers 351 are at least disposed between the gate 352 and the plurality of second indium gallium zinc oxides 332 so as to insulate the gate 352 from the plurality of second indium gallium zinc oxides 332.

In addition, in an embodiment (i.e., the embodiment shown in FIGS. 4A to 4D), in which the plurality of dielectric layers 31 are laterally thinned for multiple times and the plasma treatment is performed for two times, the gate structure 35 formed in step S26 is the same as that in this embodiment. According to the above technical solutions, the contact resistance between the plurality of second indium gallium zinc oxides and the plurality of conductive strips is reduced by forming the plurality of first indium gallium zinc oxides with a higher indium concentration between the plurality of second indium gallium zinc oxides and the plurality of conductive strips. In addition, the first indium gallium zinc oxide and the second indium gallium zinc oxide are made of the same material, thereby skipping forming an interface between the first indium gallium zinc oxide and the second indium gallium zinc oxide, so that further reduction in the contact resistance is facilitated. Furthermore, an oxygen hole concentration gradient is formed in the plurality of first indium gallium zinc oxides, such that the electric leakage of the transistor can be prevented, and thus the power consumption of a device can be reduced. In addition, by annealing the plurality of first indium gallium zinc oxides, the damage to the surfaces of the plurality of first indium gallium zinc oxides can be reduced, and the electrical properties thereof, such as conductivity, carrier concentration and mobility, can be improved.

Based on the same inventive concept, an embodiment of the present disclosure further provides a semiconductor structure.

Referring to FIG. 3H, a schematic structural diagram of a semiconductor structure according to an embodiment of the present disclosure is shown. As shown in FIG. 3H, the semiconductor structure includes: an initial structure, a plurality of first indium gallium zinc oxides 331, a plurality of second indium gallium zinc oxides 332, and a gate structure 35. The initial structure includes a plurality of dielectric layers 31 and a plurality of conductive layers 32, which are sequentially stacked along a first direction D1, where each of the conductive layers 32 includes a plurality of conductive strips 320 extending along a second direction D2 and spaced apart along a third direction D3, each of the conductive strips 320 is separated into a first part 321 and a second part 322, which are independent of each other, in the second direction D2, and the opposite end parts of the first parts 321 and the second parts 322 are recessed into the plurality of dielectric layers 31. The plurality of first indium gallium zinc oxides 331 are respectively disposed at the opposite ends of the first parts 321 and the second parts 322 of the plurality of conductive strips 320, and the end parts of the plurality of first indium gallium zinc oxides 331 protrude from the plurality of dielectric layers 31. The plurality of second indium gallium zinc oxides 332 cover the surfaces of the regions of the plurality of first indium gallium zinc oxides 331 protruding from the plurality of dielectric layers 31, and the concentration of indium in the first indium gallium zinc oxide 331 is higher than that of indium in the second indium gallium zinc oxide 332. The gate structure 35 covers the plurality of second indium gallium zinc oxides 332.

According to the technical solutions, the contact resistance between the plurality of second indium gallium zinc oxides and the plurality of conductive strips is reduced by forming the plurality of first indium gallium zinc oxides with a higher indium concentration between the plurality of second indium gallium zinc oxides and the plurality of conductive strips. In addition, the plurality of first indium gallium zinc oxides and the plurality of second indium gallium zinc oxides are made of the same material, thereby skipping forming an interface between the plurality of first indium gallium zinc oxides and the plurality of second indium gallium zinc oxides, such that further reduction in the contact resistance between the plurality of second indium gallium zinc oxides and the plurality of conductive strips is facilitated.

The gate structure, the plurality of second indium gallium zinc oxides 332, the plurality of first indium gallium zinc oxides 331 and the plurality of conductive strips form a transistor, the first parts of the plurality of conductive strips may serve as a source region of the transistor, and the second parts of the plurality of conductive strips may serve as a drain region of the transistor.

In some embodiments, the molar composition ratio of indium, gallium and zinc in the plurality of first indium gallium zinc oxides 331 is (9-10):1:1. The plurality of first indium gallium zinc oxides 331 with a high indium-gallium ratio can reduce the contact resistance between the plurality of second indium gallium zinc oxides 332 and the plurality of conductive strips.

In some embodiments, the plurality of oxygen holes 34 are formed in the plurality of first indium gallium zinc oxides 331, such that the electric leakage of the transistor can be prevented, and thus the power consumption of the device can be reduced. Different from the embodiment shown in FIG. 3H, in the embodiment shown in FIG. 4D, the concentration of a plurality of oxygen holes 34 at the end of each of the plurality of first indium gallium zinc oxides 331 proximal to the corresponding second indium gallium zinc oxide 332 is higher than that of a plurality of oxygen holes 34 on the side of the first indium gallium zinc oxide 331 distal to the second indium gallium zinc oxide 332. In addition, in the embodiment shown in FIG. 4D, the concentration of the plurality of oxygen holes 34 in the plurality of first indium gallium zinc oxides 331 exhibits a gradient decrease. An oxygen hole concentration gradient is formed in the plurality of first indium gallium zinc oxides 331, such that the conductive effect can be further improved, and thus the contact resistance between the plurality of second indium gallium zinc oxides and the plurality of conductive strips can be reduced.

It should be noted that references to “an embodiment”, “embodiments”, “exemplary embodiments”, “some embodiments”, etc. in the specification indicate that the described embodiments may include a particular feature, structure or characteristic, but every embodiment may not necessarily include the particular feature, structure or characteristic. Moreover, such phrases do not necessarily refer to the same embodiment. In addition, when a particular feature, structure or characteristic is described in conjunction with an embodiment, whether explicitly described or not, implementing such feature, structure or characteristic in conjunction with other embodiments falls in the scope of knowledge of those skilled in the relevant arts.

In general, terms may be understood, at least in part, from the usage in context. For example, depending, at least in part, on the context, the term “one or more” as used herein may be used for describing any feature, structure or characteristic in the singular sense, or may be used for describing a combination of features, structures or characteristics in the plural sense. Similarly, depending, at least in part, on the context, terms such as “one”, “a certain” or “the” may also be understood to express singular or plural usage. In additional, the term “based on” may be understood to be not necessarily intended to express a set of exclusive factors, but substitutably, similarly depending, at least in part, on the context, may allow for the presence of other factors which are not necessarily explicitly described. It should also be noted that “connection/coupling” in this specification means not only direct coupling of one component to another component but also indirection coupling of one component to another component through an intermediate component.

It should be explained that the terms “comprising” and “having” and variations thereof, involved in the present disclosure, are intended to cover non-exclusive inclusions. The terms “first” “second” and the like are used for distinguishing similar objects and are not necessarily used for describing a particular sequential or chronological order; and unless clear indication in the context, it should be understood that data used in such a manner may be interchanged where appropriate. Moreover, the embodiments in the present disclosure and the features in the embodiments may be combined with one another without conflicts. In addition, in the foregoing explanation, descriptions of commonly-known components and techniques are omitted so as to avoid unnecessarily confusing the concepts of the present disclosure. In the above embodiments, each embodiment puts emphasis on differences from other embodiments, and the same/similar parts of the embodiments may be referred to one another.

The above embodiments are only preferred embodiments of the present disclosure; and it should be noted that for those of ordinary skill in the art, numerous improvements and refinements may be made without departing from the principle of the present disclosure, and such improvements and refinements should be also regarded to fall within the scope of protection of the present disclosure.

What is claimed is:

1. A method for manufacturing a semiconductor structure, comprising:
providing an initial structure comprising a plurality of dielectric layers and a plurality of conductive layers, which are sequentially stacked along a first direction, wherein each of the conductive layers comprises a plurality of conductive strips extending along a second direction and spaced apart along a third direction, a plurality of first holes penetrate through the plurality of dielectric layers and the plurality of conductive strips along the first direction, and each of the conductive strips is separated by the corresponding first hole into two parts, which are independent of each other, in the second direction;
laterally thinning the plurality of conductive strips along the second direction to form a plurality of first trenches between two adjacent dielectric layers;
forming a plurality of first indium gallium zinc oxides in the plurality of first trenches;
laterally thinning the plurality of dielectric layers along the second direction to expose part of the plurality of first indium gallium zinc oxides and form a plurality of second trenches between two adjacent first indium gallium zinc oxides;
forming a plurality of second indium gallium zinc oxides on surfaces of the plurality of exposed first indium gallium zinc oxides, wherein a concentration of indium in the plurality of first indium gallium zinc oxides is higher than a concentration of indium in the plurality of second indium gallium zinc oxides; and
forming a gate structure in the plurality of first holes and the plurality of second trenches.

2. The method according to claim 1, wherein after the step of laterally thinning the plurality of dielectric layers along the second direction, the method further comprises: performing plasma treatment to the plurality of exposed first indium gallium zinc oxides so as to form a plurality of oxygen holes in the plurality of first indium gallium zinc oxides.

3. The method according to claim 2, wherein in the process of performing the plasma treatment to the plurality of exposed first indium gallium zinc oxides, a plasma concentration decreases with a treatment time.

4. The method according to claim 1, wherein in the step of laterally thinning the plurality of dielectric layers along the second direction, the plurality of dielectric layers are laterally thinned along the second direction for multiple times to partially expose the plurality of first indium gallium zinc oxides; and
after the plurality of dielectric layers are laterally thinned along the second direction each time, treatment to the plurality of exposed first indium gallium zinc oxides is performed so as to form a plurality of oxygen holes in the plurality of first indium gallium zinc oxides.

5. The method according to claim 4, in the step of performing the treatment to the plurality of exposed first indium gallium zinc oxides after the plurality of dielectric layers are laterally thinned along the second direction each time, plasma treatment to the plurality of exposed first indium gallium zinc oxides is performed after the plurality of dielectric layers are laterally thinned each time, and a plasma concentration decreases with an increase of the times of laterally thinning the plurality of dielectric layers so as to form an oxygen hole concentration gradient in the plurality of first indium gallium zinc oxides.

6. The method according to claim 2, wherein after performing the plasma treatment to the plurality of first indium gallium zinc oxides, the method further comprises: annealing the plurality of first indium gallium zinc oxides.

7. The method according to claim 1, wherein a molar composition ratio of indium, gallium and zinc in the plurality of first indium gallium zinc oxides is (9-10):1:1.

8. A semiconductor structure, comprising:
an initial structure comprising a plurality of dielectric layers and a plurality of conductive layers, which are sequentially stacked along a first direction, wherein each of the plurality of conductive layers comprises a plurality of conductive strips extending along a second direction and spaced apart along a third direction, each of the plurality of conductive strips is separated into a first part and a second part, which are independent of each other, in the second direction, and opposite end parts of the first parts and the second parts are recessed into the plurality of dielectric layers;
a plurality of first indium gallium zinc oxides respectively disposed at the opposite end parts of the first parts and the second parts of the plurality of conductive strips, wherein end parts of the plurality of first indium gallium zinc oxides protrude from the plurality of dielectric layers;
a plurality of second indium gallium zinc oxides covering surfaces of regions of the plurality of first indium gallium zinc oxides protruding from the plurality of dielectric layers, wherein a concentration of indium in the plurality of first indium gallium zinc oxides is higher than a concentration of indium in the plurality of second indium gallium zinc oxides;
and a gate structure covering the plurality of second indium gallium zinc oxides.

9. The semiconductor structure according to claim 8, wherein a concentration of a plurality of oxygen holes at an end of each of the plurality of first indium gallium zinc oxides proximal to the corresponding second indium gallium zinc oxide is higher than a concentration of a plurality of oxygen holes on a side of the first indium gallium zinc oxide distal to the second indium gallium zinc oxide.

10. The semiconductor structure according to claim 9, wherein the concentration of the plurality of oxygen holes in the plurality of first indium gallium zinc oxides exhibits a gradient decrease.

11. The semiconductor structure according to claim 8, wherein a molar composition ratio of indium, gallium and zinc in the plurality of first indium gallium zinc oxides is (9-10):1:1.

12. The semiconductor structure according to claim 9, wherein a molar composition ratio of indium, gallium and zinc in the plurality of first indium gallium zinc oxides is (9-10):1:1.

13. The semiconductor structure according to claim 10, wherein a molar composition ratio of indium, gallium and zinc in the plurality of first indium gallium zinc oxides is (9-10):1:1.

14. The semiconductor structure according to claim 8, wherein the gate structure, the plurality of second indium gallium zinc oxides, the plurality of first indium gallium zinc oxides and the plurality of conductive strips form a transistor, the first parts of the plurality of conductive strips serve as a source region of the transistor, and the second parts of the plurality of conductive strips serve as a drain region of the transistor.

15. The semiconductor structure according to claim 14, wherein the gate structure further comprises a gate and gate dielectric layers, wherein the gate dielectric layers are at least disposed between the gate and the plurality of second indium gallium zinc oxides.
